(19) United States
(12) Patent Application Publication
(10) Pub. No.: US 2014/0084410 A1
(43) Pub. Date: Mar. 27, 2014

(54) SOLID-STATE IMAGING DEVICE

(71) Applicant: FUJIFILM Corporation, Tokyo (JP)

(72) Inventor: Mitsuru OKIGAWA, Saitama-shi (JP)

(73) Assignee: FUJIFILM Corporation, Tokyo (JP)

(21) Appl. No.: 14/092,625

(22) Filed: Nov. 27, 2013

Related U.S. Application Data
(63) Continuation of application No. PCT/JP2012/063162, filed on May 23, 2012.

(30) Foreign Application Priority Data
Jun. 2, 2011 (JP) 2011-124389

(51) Int. Cl. H01L 27/146

(52) U.S. Cl. CPC H01L 27/1464
USPC 257/447

(57) ABSTRACT

A solid-state imaging device has an element substrate that is formed with a plurality of photodiodes, a back-surface electrode, and an electric charge discharging path. A wiring layer for controlling the photodiodes is formed in a front surface of the element substrate. Light is incident upon the photodiodes from a back surface of the element substrate. By applying the back-surface electrode with a voltage in accordance with timing of operation control of the photodiodes, a potential is modulated in the vicinity of the back surface of the element substrate. When an electron inversion layer formed in the vicinity of the back surface of the element substrate upon applying a positive voltage to the back-surface electrode is coupled to a region for accumulating signal charge through a monotonously changing potential gradient, the electric charge that has flowed into the electron inversion layer is discharged through the electric charge discharging path.

### BACKGROUND OF THE INVENTION

1. Field of the Invention

The present invention relates to a back-surface irradiation type solid-state imaging device in which light is applied to a back surface of an element substrate.

2. Description Related to the Prior Art

Conventionally, a CMOS imaging device is known as a solid-state imaging device that is suitable for use in a digital camera or the like. The CMOS imaging device (hereinafter simply called solid-state imaging device) is constituted of a silicon substrate (element substrate) formed with photodiodes (PDs) in its surface, a wiring layer having electrodes, wiring, and the like for controlling the photodiodes, a color filter, microlenses, and the like that are stacked in this order. Light from an object passes through the microlens and the color filter, and is incident upon the photodiode through the multilayer metal wiring. In such a so-called front-surface irradiation type imaging device, the metal wiring restricts an aperture ratio. Also, in the front-surface irradiation type imaging device, increase in a pixel number downsizes individual pixels and makes the electrodes and the wiring stacked in more layers. This causes the wiring layer to be deeper and hence the aperture ratio to be lower.

Accordingly, a back-surface irradiation type imaging device has been adopted in recent years in which even if a pixel number is increased, a wiring layer does not affect the aperture ratio. In the back-surface irradiation type imaging device, transistors and a multilayer wiring layer are provided on a back side of the photodiodes when viewed from a light incident direction. Light is incident upon a back surface of the element substrate formed with the photodiodes, and reaches the photodiode through the microlens and the color filter without being blocked by the multilayer metal wiring.

In the back-surface irradiation type imaging device, an interface state between silicon being a photoelectric conversion region and an insulating film provided on the back surface (light incident surface) brings about the occurrence of a dark current and a white defect, and causes noise. Therefore, according to the back-surface irradiation type imaging device, this noise is suppressed using a method of accumulating holes in this interface.

There are known a plurality of methods of accumulating holes in the back-surface side silicon-insulating layer interface in the vicinity of the back surface of the element substrate. For example, a method is known in which the back-surface side silicon-insulating layer interface is doped with acceptors such as boron.

Another method of accumulating holes in the back-surface side silicon-insulating layer interface is known in which a transparent electrode is provided on the insulating film on the back surface side and a negative voltage is applied to the transparent electrode (refer to US Patent Application Publication No. 2013/0044245 corresponding to Japanese Patent Laid-Open Publication No. 2006-261638, US Patent Application Publication No. 2012/0147241 corresponding to Japanese Patent Laid-Open Publication No. 2007-258684, and Japanese Patent Laid-Open Publication No. 2009-278129). Likewise, further another method of accumulating holes in the back-surface side silicon-insulating layer interface is known in which a ferroelectric thin film such as HfO₂, which is known as a high-k film (an insulating film having a high relative dielectric constant) used as a gate insulating film for suppressing a gate leak current in a MOS semiconductor, is provided on the back-surface side insulating film and polarized by heating. Moreover, further another method is known in which a dielectric thin film (silicon nitride film) injected with fixed charge by irradiation with ultraviolet rays or application of an electric field is provided.

In the back-surface irradiation type imaging device, unnecessary electric charge being the noise is discharged by the accumulation of the holes in the back-surface side silicon-insulating layer interface in the vicinity of the back surface of the element substrate. In the back-surface irradiation type imaging device, however, another problem occurs due to increase in a pixel number. That is, high-intensity incident light produces too much amount of electric charge to hold in a charge accumulation capacity of a pixel. The electric charge flows over an adjoining pixel and degrades image quality. However, it is difficult for the back-surface irradiation type imaging device to provide large space for discharging the unnecessary electric charge.

Out of the front-surface irradiation type imaging device, for example, an imaging device using an n-type element substrate as the element substrate formed with the photodiodes in its surface has a so-called vertical overflow drain structure in which unnecessary electric charge is discharged into the large n-type element substrate on a back surface side. On the other hand, in the back-surface irradiation type imaging device, the excessive electric charge is discharged into a small n+ region on a front surface side, being part of an area applied with a positive voltage. The finer the pixel, the more difficult it becomes to expand the n+ region, because this surface (front surface) is provided with gate electrodes, wiring, and the like. Furthermore, the light incident surface has to be made of a p-type semiconductor to accumulate the electric charge, and the vertical overflow drain structure cannot be formed due to slimming.

As described above, if increase in a pixel number is not required, a path from each pixel to the n+ region can be formed in an adequate size. However, increase in a pixel number makes it difficult to allocate the path to the n+ region in the adequate size. Furthermore, although it is specific to the back-surface irradiation type imaging device, the back surface side has to be formed with p-type silicon, and hence the n-type element substrate is unusable for discharging electric charge.

For this reason, in the back-surface irradiation type imaging device having a large number of pixels, it is hard to form the overflow drain structure and allocate the space for discharging the unnecessary electric charge.

In addition, when the holes are accumulated in the back-surface side silicon-insulating layer interface, as described in the above patent documents, since a constant voltage is evenly applied to the vicinity of the back surface (especially, to the silicon-insulating layer interface), a potential distribution in the vicinity of the back surface and a potential distribution of the photodiode (the photoelectric conversion region) are uniform without variation with time. Thus, in the case of switching between 2D imaging and 3D imaging or adjusting a parallax angle in the 3D imaging by using a monocular 3D device (an imaging device that obtains stereoscopic image by one imaging section), it is required to modulate the potential of the photoelectric conversion region. However, the devices of the above patent documents cannot deal with the modulation.

### SUMMARY OF THE INVENTION

An object of the present invention is to provide a back-surface irradiation type imaging device that can secure a part for discharging unnecessary electric charge and adjust a parallax angle in 3D imaging.

To achieve the above and other objects, a solid-state imaging device according to the present invention includes an element substrate, a back-surface electrode, and an electric charge discharging path. The element substrate is formed with a plurality of photodiodes each for producing signal charge in accordance with an amount of incident light and accumulating the signal charge. A wiring layer for controlling the photodiodes is formed on a front surface of the element substrate. The light is incident upon the photodiodes from a back surface of the element substrate. The back-surface electrode, which is provided on the back surface of the element substrate, modulates a potential in the vicinity of the back surface of the element substrate by being applied with a voltage in accordance with timing of operation control of the photodiode. The electric charge discharging path, which is provided in the element substrate, discharges electric charge that has flowed into an electron inversion layer, when the electron inversion layer formed in the vicinity of the back surface of the element substrate upon applying a positive voltage to the back-surface electrode is coupled to a region for accumulating the signal charge through a monotonously changing potential gradient. When electrons exist as a carrier, the electron inversion layer is similar to an inversion layer formed in the vicinity of a back surface of p-type silicon, and has a deep potential for the electrons.

The back-surface electrode is preferably applied with a positive voltage in an accumulation period in which the photodiode accumulates the signal charge upon receiving incidence of the light. Thus, the electron inversion layer is formed in the vicinity of the back surface of the element substrate separately from an accumulation region in which the photodiode accumulates the signal charge.

The back-surface electrode is preferably applied with a negative voltage in the accumulation period in which the photodiode accumulates the signal charge upon receiving incidence of the light. Thus, a hole accumulation layer is formed in the vicinity of the back surface of the element substrate.

The back-surface electrode is preferably applied with a positive voltage in a reset period for abandoning the signal charge. Thus, the electron inversion layer is formed in the vicinity of the back surface of the element substrate so as to be coupled to the accumulation region in which the photodiode accumulates the signal charge.

It is preferable that the back-surface electrode is applied alternately with a positive voltage and a negative voltage in the reset period for abandoning the signal charge.

It is preferable that the back-surface electrode is provided uniformly so as to cover the plurality of photodiodes.

The back-surface electrode preferably includes a first electrode disposed on an element separation region for partitioning the plurality of photodiodes and a second electrode disposed on the photodiode. The first electrode is used for modulating a potential in the vicinity of the element separation region in accordance with an operation of the photodiode by being applied with a voltage in accordance with the operation of the photodiode. The second electrode is used for forming a hole accumulation layer in the vicinity of the back surface on the photodiode.

The second electrode is preferably applied with a negative voltage. Thus, the hole accumulation layer is formed in the vicinity of the back surface on the photodiode.

The second electrode may be made of a ferroelectric thin film. In this case, the hole accumulation layer is formed in the vicinity of the back surface on the photodiode by polarizing the ferroelectric thin film.

The second electrode may be a thin film injected with fixed charge. In this case, the fixed charge forms the hole accumulation layer in the vicinity of the back surface on the photodiode.

The first and second electrodes are preferably provided along a column direction of an array of the photodiodes.

The back-surface electrode preferably includes a plurality of individual electrodes provided on a row-by-row basis of the photodiodes. A voltage is applied to each of the individual electrodes.

In this case, by adjusting a voltage to be applied to each of the individual electrodes, the electric charge that has flowed into the electron inversion layer may be transferred in a column direction of the photodiodes.

By applying a predetermined positive voltage to the back-surface electrode, the electron inversion layer is preferably formed so as to be coupled to the region for accumulating the signal charge. Thus, the signal charge flows into the electron inversion layer and is transferred through the electron inversion layer.

In transferring the signal charge by the electron inversion layer, the signal charge obtained from the plurality of photodiodes may be added.

The back-surface electrode is preferably formed in a lattice shape on the element separation region for partitioning the plurality of photodiodes, such that an opening is situated on the photodiode.

The back-surface electrode preferably includes a plurality of individual electrodes provided separately on a column-by-column basis or a row-by-row basis of the photodiodes. In this case, the back-surface electrode is preferably made of a light shielding material.

A peripheral circuit for controlling an operation of the solid-state imaging device is preferably laid out around a pixel section having an array of the photodiodes, and a second back-surface electrode is preferably provided on an area corresponding to the peripheral circuit in the back surface of the element substrate.

It is preferable that the second back-surface electrode is provided separately on an analog circuit area and a digital circuit area.

According to the present invention, a potential distribution of a back surface side silicon-insulating layer interface and a photoelectric conversion region is modulated with time. Thus, it is possible to efficiently discharge unnecessary electric charge, and adjust a parallax angle.

### BRIEF DESCRIPTION OF THE DRAWINGS

For more complete understanding of the present invention, and the advantage thereof, reference is now made to the subsequent descriptions taken in conjunction with the accompanying drawings, in which:

FIG. 1 is a cross-sectional view showing the schematic structure of an imaging device according to a first embodiment;

FIG. 2 is a top plan view showing the structure of the imaging device;

FIG. 3 is an explanatory view showing an example of a potential formed by a back-surface electrode;

FIG. 4 is a waveform chart showing an example of a voltage to be applied to the back-surface electrode in accordance with an operation of the imaging device;

FIG. 5 is a waveform chart showing an operation state in which a negative voltage is applied to the back-surface electrode in an accumulation period;

FIG. 6 is a waveform chart showing an operation state in which a positive voltage and a negative voltage are alternately applied to the back-surface electrode in a reset period;

FIG. 7 is a cross-sectional view showing an insulating film forming step in a manufacturing method of a solid-state imaging device according to the present invention;

FIG. 8 is a cross-sectional view showing a deposition step;

FIG. 9 is a cross-sectional view showing a MOS structure forming step;

FIG. 10 is a cross-sectional view showing an ion implantation step;

FIG. 11 is a cross-sectional view showing a first support substrate adhering step;

FIG. 12 is a cross-sectional view showing a splitting step;

FIG. 13 is a cross-sectional view showing an element forming step;

FIG. 14 is a cross-sectional view showing a wiring layer forming step and a second support substrate adhering step;

FIG. 15 is a cross-sectional view showing a first support substrate removing step;

FIG. 16 is a cross-sectional view showing a wiring connecting step, and a color filter forming step and a microlens forming step following thereto;

FIG. 17 is a cross-sectional view showing the structure of an imaging device according to a second embodiment;

FIG. 18 is an explanatory view showing a pixel arrangement of the imaging device according to the second embodiment;

FIG. 19 is an explanatory view showing a state of a back-surface electrode of the second embodiment;

FIG. 20 is an explanatory view showing an operation state of the imaging device according to the second embodiment;

FIG. 21 is a cross-sectional view of a modification example in which a ferroelectric thin film is used as the back-surface electrode;

FIG. 22 is an explanatory view showing a state of the back-surface electrode of the modification example;

FIG. 23 is an explanatory view of an operation state of the modification example;

FIG. 24 is a cross-sectional view showing the structure of an imaging device according to a third embodiment;

FIG. 25 is an explanatory view showing a state of a back-surface electrode according to the third embodiment;

FIG. 26 is an explanatory view showing a state in which the back-surface electrode transfers electric charge;

FIG. 27 is an explanatory view showing a modification example in which the back-surface electrode individually transfers the electric charge of each pixel;

FIG. 28 is an explanatory view showing a modification example in which the back-surface electrode transfers electric charge;

FIG. 29 is an explanatory view showing another state of a back-surface electrode;

FIG. 30 is an explanatory view showing further another state of a back-surface electrode;

FIG. 31 is an explanatory view showing further another state of a back-surface electrode;

FIG. 32 is an explanatory view showing further another state of a back-surface electrode;

FIG. 33 is an explanatory view showing an example in which back-surface electrodes are provided so as to correspond to peripheral circuits and the like; and

FIG. 34 is an explanatory view showing another example in which back-surface electrodes are provided so as to correspond to peripheral circuits.

### DESCRIPTION OF THE PREFERRED EMBODIMENTS

### First Embodiment

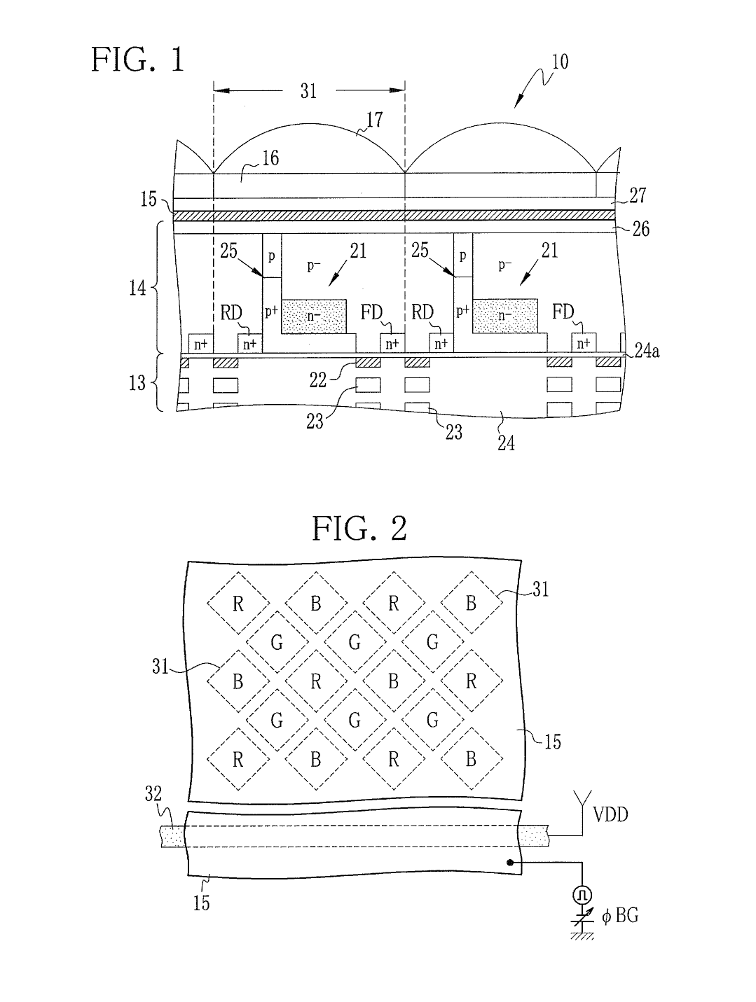

As shown in FIG. 1, an imaging device 10 being aback-surface irradiation type imaging device is provided with a wiring layer 13, an element substrate 14, a back-surface electrode 15, a color filter 16, microlenses 17, and the like. The wiring layer 13, the element substrate 14, the color filter 16, and the microlenses 17 are stacked in this order on a support substrate 49 (see FIG. 16). The support substrate 49 is, for example, a silicon substrate as described later on.

In the wiring layer 13, gate electrodes 22 and wiring 23 are stacked via an interlayer insulating film 24. The gate electrode 22 controls accumulation of signal charge to a photodiode 21 and readout of the signal charge therefrom. A signal obtained by the photodiode 21 is led through the wiring 23 to an amplifier and the like. There is provided an insulating film 24a in an interface between the wiring layer 13 and the element substrate 14, and the gate electrodes 22 are disposed on the insulating film 24a. When a front surface refers to a side of the wiring layer 13 with respect to the photodiodes 21, as in the case of a front-surface irradiation type imaging device, the support substrate 49 is in a frontmost surface of the imaging device 10, and the wiring layer 13 is under the support substrate 49. The microlenses 17 are provided in a backmost surface of the imaging device 10. Light from an object is incident upon the imaging device 10 from a back surface.

The element substrate 14 is a silicon substrate in which floating diffusion regions (FDs), reset drains (RDs), various types of MOS transistors, and the like are formed. The wiring layer 13 is provided on a surface of the element substrate 14 on a side of the elements. The gate electrodes 22 and the wiring 23 of the wiring layer 13 are formed in accordance with the positions of the photodiodes 21, the floating diffusion regions, and the reset drains. An element separation region 25 is formed around the photodiode 21. The element separation region 25 is conventionally formed of a p+ layer. In the imaging device 10, however, the element separation region 25 is formed of a p+ layer on a front surface side, and a p layer on a back surface side. This is for the purpose of facilitating formation of an electron inversion layer 38, which will be described later on. An insulating layer 26 made of SiO₂ is formed in a backmost surface of the element substrate 14. One photodiode 21 composes one pixel 31.

The photodiode 21 produces signal charge by an amount corresponding to an amount of incident light by photoelectric conversion. Most of the produced signal charge is accumulated in a potential well formed in an n− layer. The accumulation of the signal charge in the photodiode 21 is performed in a signal charge accumulation period predetermined in accordance with an exposure and the like. The signal charge in the photodiode 21 is transferred to the floating diffusion region by controlling the gate electrode 22, and converted into a voltage through the wiring 23. The voltage is amplified by an amplifying transistor (not shown), and read out as an imaging signal. After an output of the imaging signal corresponding to the signal charge, the signal charge that becomes unnecessary is discharge from the floating diffusion region to the reset drain applied with a power voltage VDD by controlling the gate electrode 22.

The back-surface electrode 15 is a transparent electrode provided on the insulating layer 26 being the back surface of the element substrate 14. The back-surface electrode 15 is made of, for example, an ITO (indium tin oxide) film, polycrystalline silicon, or the like. The back-surface electrode 15, silicon of the element substrate 14, and the insulating layer 26 compose a MOS structure. To the back-surface electrode 15, a voltage φBG (see FIG. 2), which corresponds to operation timing of the imaging device 10 and an incident light amount, is applied. Thus, the back-surface electrode 15 forms an electron inversion layer and a hole accumulation layer in an interface between the silicon of the element substrate 14 and the insulating layer 26. An insulating layer 27 made of SiO₂ or the like is formed on the back-surface electrode 15.

The color filter 16 is a primary color filter having BGR three color segments, for example. The color filter 16 filters light that is incident upon the microlens 17 and reaches the photodiode 21, and transmits one of BGR colors. The color filter 16 is provided on the insulating layer 27 such that one color segment corresponds to one photodiode 21 in the imaging device 10.

The microlens 17 gathers the incident light to the photodiode 21 disposed in a corresponding position. A plurality of microlenses 17 are provided on the backmost surface of the imaging device 10 being a light incident surface such that each microlens 17 corresponds to each photodiode 21.

As shown in FIG. 2, a plurality of pixels 31 are provided in a so-called honeycomb array in which a square lattice array is tilted by 45 degrees. In the color filter 16, the number of green (G) pixels is twice as large as that of red (R) pixels or blue (B) pixels.

The imaging device 10 is provided with an n+ diffusion layer 32 next to a pixel section having the array of the pixels 31. The n+ diffusion layer 32 is provided in the element substrate 14, and applied with the power voltage (VDD). The n+ diffusion layer 32 is a discharge path for discharging electric charge (electrons). By applying a positive voltage to the back-surface electrode 15, the n+ diffusion layer 32 is coupled to the electron inversion layer (described later) formed in the interface between the silicon of the element substrate 14 and the insulating layer 26. Therefore, the electric charge that has flowed from each pixel into the electron inversion layer is discharged.

The back-surface electrode 15 is uniformly provided so as to cover all the pixels 31 and the n+ diffusion layer 32. The voltage φBG is applied to the back-surface electrode 15 in a pulse form. The voltage φBG to be applied to the back-surface electrode 15 is variable. The polarity and the level of voltage φBG to be applied to the back-surface electrode 15 are determined in accordance with various types of operation timing including an accumulation period, a readout period, and reset, an exposure, and the like.

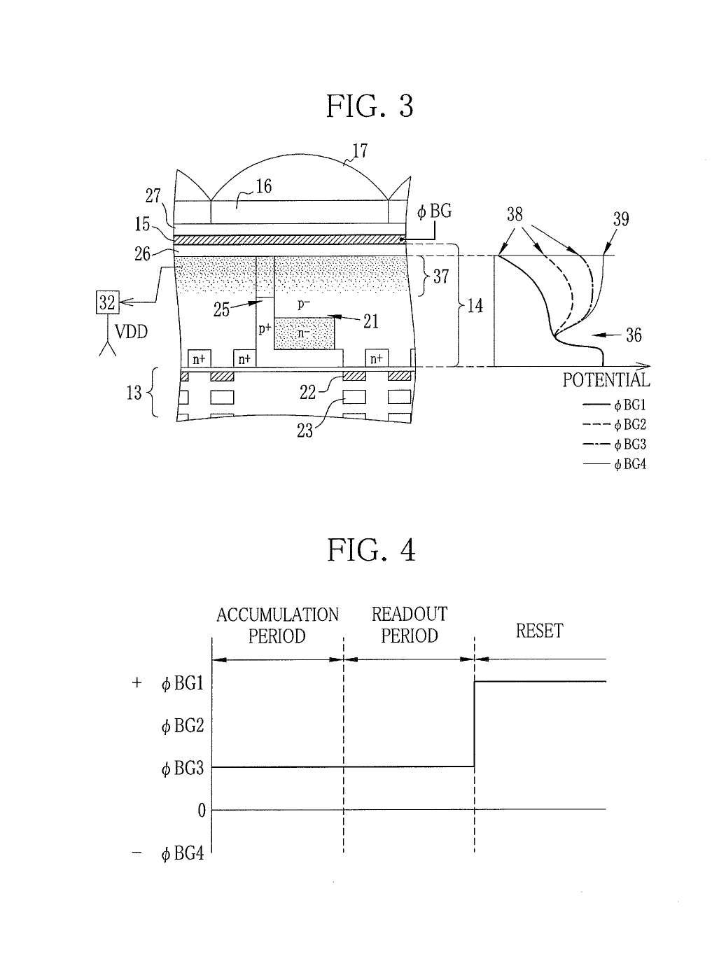

As shown in FIG. 3, four types of voltages φBG1 to φBG4 are applied to the back-surface electrode 15. The voltages φBG1 to φBG3 have positive values and a magnitude relation of φBG1>φBG2>φBG3>0. On the other hand, the voltage φBG4 has a negative value (φBG4<0). Upon applying the positive voltage φBG1 to φBG3 to the back-surface electrode 15, a portion 38 having a deep potential level relative to electrons is formed in an interface 37 (positioned in the vicinity of the back surface; hereinafter called silicon-insulating layer interface) between the silicon of the element substrate 14 and the insulating layer 26. This portion 38 having a deep potential level relative to electrons will be hereinafter called an electron inversion layer 38, due to similarity to an inversion layer to be formed in the vicinity of a back surface of p-type silicon when electrons exist as a carrier. The electron density of the electron inversion layer 38 or a potential depth thereof varies in accordance with a level of the positive voltage φBG to be applied to the back-surface electrode 15. The higher the level of the positive voltage φBG applied, the higher the electron density becomes.

For example, the electron inversion layer 38 formed by application of the positive voltage φBG3 to the back-surface electrode 15 is shallow, and a potential barrier corresponding to the voltage level partitions the electron inversion layer 38 from a potential well (hereinafter called accumulation layer) 36 formed in the vicinity of an n− region of the photodiode 21. Thus, when light is incident upon the photodiode 21 in a state of being applied with the positive voltage φBG3 to the back-surface electrode 15, signal charge (electrons) produced in the photodiode 21 is accumulated to the accumulation layer 36. On the other hand, a dark current, which occurs in the silicon-insulating layer interface 37 independently of incidence of light, flows into the electron inversion layer 38. Also, in a case where the intensity of the incident light is too high, excessive signal charge produced beyond an accumulation capacity of the accumulation layer 36 surmounts the potential barrier and flows into the electron inversion layer 38.

Since the back surface side of the element separation region 25 is made of the p layer, when the positive voltage φBG is high, the electron inversion layer 38 extends continuously to the element separation region 25 almost similarly to the photodiode 21. As described above, the back-surface electrode 15 extends even to the n+ diffusion layer 32. Thus, the electron inversion layer 38 is formed continuously over a plurality of pixels 31 and coupled to the n+ diffusion layer 32 through a monotonously changing potential gradient. Accordingly, the signal charge that has flowed into the electron inversion layer 38 as described above is discharged through the electron inversion layer 38 to the n+ diffusion layer 32.

When the larger positive voltage φBG2 is applied to the back-surface electrode 15, the electron inversion layer 38 becomes deeper. The electron inversion layer 38 is formed so as to be separated from the accumulation layer 36 by a potential barrier corresponding to the level of the positive voltage φBG2. Thus, when the positive voltage φBG2 is applied to the back-surface electrode 15, the signal charge produced in the photodiode 21 is accumulated in the accumulation layer 36. The dark current and the excessive signal charge flow into the electron inversion layer 38 and are discharged to the n+ diffusion layer 32. Note that, the potential barrier formed between the electron inversion layer 38 and the accumulation layer 36 becomes lower than that formed by application of the positive voltage φBG3, and the accumulation capacity of the accumulation layer 36 becomes less.

When the further larger positive voltage φBG1 is applied to the back-surface electrode 15, the electron inversion layer 38 becomes further deeper than that formed by application of the positive voltage φBG2. At the same time, no potential barrier is formed between the electron inversion layer 38 and the accumulation layer 36. The electron inversion layer 38 and the accumulation layer 36 are coupled through a monotonously changing potential gradient. Therefore, when the positive voltage φBG1 is applied to the back-surface electrode 15, all of the signal charge accumulated in the accumulation layer 36, the signal charge produced in the photodiode 21, and the dark current occurring in the silicon-insulating layer interface 37 flow into the electron inversion layer 38 and are discharged to the n+ diffusion layer 32.

When the negative voltage φBG4 is applied to the back-surface electrode 15, on the other hand, a potential ascends in an area from the accumulation layer 36 to the silicon-insulating layer interface 37 without descending in the vicinity of the insulation layer 26. The accumulation capacity of the accumulation layer 36 is maximized, and the sensitivity of each pixel 31 is improved. When the negative voltage φBG4 is applied to the back-surface electrode 15, holds (positive holes) are attracted to the silicon-insulating layer interface 37, so the hole accumulation layer 39 is formed. The dark current occurring in the silicon-insulating layer interface 37 is recombined with the holes of the hole accumulation layer 39 and disappears.

The operation of the imaging device 10 structured as above will be hereinafter described. As shown in FIG. 4, the positive voltage φBG3 is applied to the back-surface electrode 15 in an accumulation period for accumulating the signal charge to the accumulation layer 36 upon receiving the light from the object and a readout period for outputting the imaging signal. Ina reset period for resetting the pixels 31 by abandoning the signal charge and the like, the positive voltage φBG1 is applied to the back-surface electrode 15.

In the accumulation period, the signal charge is accumulated to the accumulation layer 36 by an amount corresponding to the amount of incident light. At the same time, the application of the positive voltage φBG3 to the back-surface electrode 15 forms the electron inversion layer 38 in the silicon-insulating layer interface 37. Thus, the dark current that has occurred in the silicon-insulating layer interface 37 is discharged through the electron inversion layer 38 to the n+ diffusion layer 32. In a case where a large amount of signal charge to the extent of exceeding the accumulation capacity is produced by the incident light of high intensity, the excessive signal charge overflows the accumulation layer 36 and surmounts the potential barrier formed between the accumulation layer 36 and the electron inversion layer 38. The excessive signal charge flows into the electron inversion layer 38 and is discharged to the n+ diffusion layer 32. Accordingly, the excessive signal charge is discharged through the electron inversion layer 38 without flowing into the accumulation layer 36 of another pixel.

In the readout period, the signal charge accumulated in the accumulation layer 36 is transferred to the floating diffusion region by control of a voltage to be applied to the gate electrode 22. The imaging device 10 outputs a voltage signal as the imaging signal that corresponds to the amount of the signal charge transferred to the floating diffusion region. At this time, by the application of the positive voltage φBG3 to the back-surface electrode 15, the dark current occurring in the silicon-insulating layer interface 37 is continuously discharged through the electron inversion layer 38 to the n+ diffusion layer 32.

In the reset period, the signal charge transferred to the floating diffusion region is further transferred to the reset drain for abandonment by control of a voltage to be applied to the gate electrode 22. At this time, a voltage to be applied to the back-surface electrode 15 is increased to the positive voltage φBG1, so the electron inversion layer 38 and the accumulation layer 36 are combined through the monotonously changing potential gradient. Thus, the signal charge produced in the readout period is discharged through the electron inversion layer 38 to the n+ diffusion layer 32, and all the signal charge in the pixels 31 is abandoned.

As described above, the imaging device 10 is provided with the back-surface electrode 15. By applying the back-surface electrode 15 with the voltage φBG in accordance with operation timing, the electron inversion layer 38 is formed in a required state in the silicon-insulating layer interface 37, and unnecessary electric charge including the dark current, the excessive signal charge, and the like is discharged through the electron inversion layer 38 to the n+ diffusion layer 32.

Therefore, in the imaging device 10, the unnecessary electric charge is appropriately discharged without disposing a fixed path between the accumulation layer 36 and the n+ diffusion layer 32 in advance by ion implantation, electrode formation, or the like. Thus, it is possible for the imaging device 10 to appropriately discharge the unnecessary electric charge even if the imaging device 10 has a large number of pixels.

An electric charge discharging path, which is composed of the n+ diffusion layer 32 and the electron inversion layer 38 formed by application of the positive voltage to the back-surface electrode 15, functions as a so-called overflow drain. For this reason, not only just in the case of eliminating a noise component such as the dark current occurring in the silicon-insulating layer interface 37, but also in a case where the incident light of too high intensity produces a large amount of signal charge to the extent of exceeding the capacity of the accumulation layer 36, the excessive signal charge is appropriately discharged without overflowing into another pixel 31.

Note that, the positive voltage φBG3 is applied to the back-surface electrode 15 in the accumulation period and the readout period, but a positive voltage to be applied to the back-surface electrode 15 in the accumulation period and the readout period may be φBG2. In the case of making the electric charge discharging path composed of the electron inversion layer 38 and the n+ diffusion layer 32 function as the overflow drain, the magnitude of positive voltage to be applied to the back-surface electrode 15 in the accumulation period and the readout period is arbitrary as long as the accumulation layer 36 and the electron inversion layer 38 are formed separately, and determined in accordance with an exposure, an imaging condition, and the like.

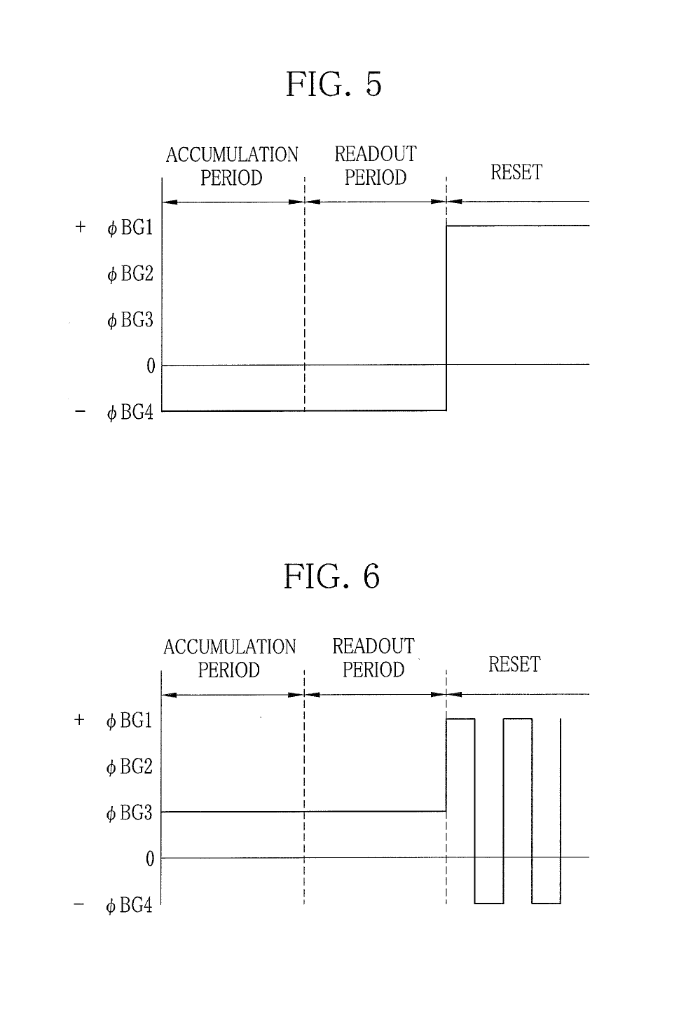

The positive voltage is applied to the back-surface electrode 15 in the accumulation period and the readout period as an operation state of the imaging device 10, but the operation state is not limited to this. For example, as shown in FIG. 5, the negative voltage φBG4 may be applied to the back-surface electrode 15 in the accumulation period and the readout period. In this case, since the electron inversion layer 38 is not formed, no overflow drain structure is composed. However, the accumulation capacity of the accumulation layer 36 becomes maximum, and the sensitivity of the pixel 31 is improved. At the same time, the application of the negative voltage φBG4 to the back-surface electrode 15 forms the hole accumulation layer 39 in the silicon-insulating layer interface 37. The existence of holes attracted to the hole accumulation layer 39 reduces a free electron density and prevents the occurrence of electrons in the dark current occurring in the silicon-insulating layer interface 37. As a result, it is possible to restrain a noise caused by the dark current occurring in the interface 37.

Furthermore, an example of continuously applying the positive voltage φBG1 in the reset period is described as an operation state of the imaging device 10, but as shown in FIG. 6, the positive voltage φBG1 and the negative voltage φBG4 may be applied alternately in the reset period, for example.

Such a clocking operation, in which the positive voltage φBG1 and the negative voltage φBG4 are applied alternately in the reset period, forms the electron inversion layer 38 and the hole accumulation layer 39 alternately in the silicon-insulating layer interface 37, and facilitates recombination of electric charge to be discharged and holes attracted to the hole accumulation layer 39 and disappearance thereof. The distance from the accumulation layer 36 to the silicon-insulating layer 37, and the distance from the accumulation layer 36 to the n+ diffusion layer 32 through the electron inversion layer 38 are long as compared with the distance from the accumulation layer 36 to the floating diffusion region, so discharging electric charge using the n+ diffusion layer 32 requires some time. However, since the clocking operation performs the recombination of electrons and holes in the silicon-insulating layer interface 37, which is near a place of occurrence of the electrons, it is possible to make the electric charge discharged (disappear) in shorter time.

The clocking operation in which the positive voltage φBG1 and the negative voltage φBG4 are alternately applied is a so-called alternating current operation, and produces a predetermined potential distribution in the silicon-insulating layer interface 37. The potential distribution produced by the clocking operation is determined by a distributed parameter circuit, which depends on a capacitance between the back-surface electrode 15 and the element substrate (silicon) 14 and an electric resistance of the back-surface electrode 15. Thus, appropriately choosing a frequency of the clocking operation shifts the potential distribution. In other words, the clocking operation corresponds to control of the potential gradient and distribution descending to the side of the insulating layer 26, and substantially makes it possible to vary a volume of an electric charge discharging region. When compared to application of just the positive voltage φBG1 to the back-surface electrode 15, which does not allow the shift of the potential distribution, the clocking operation facilitates discharge of the electric charge.

(Manufacturing Method of Imaging Device)

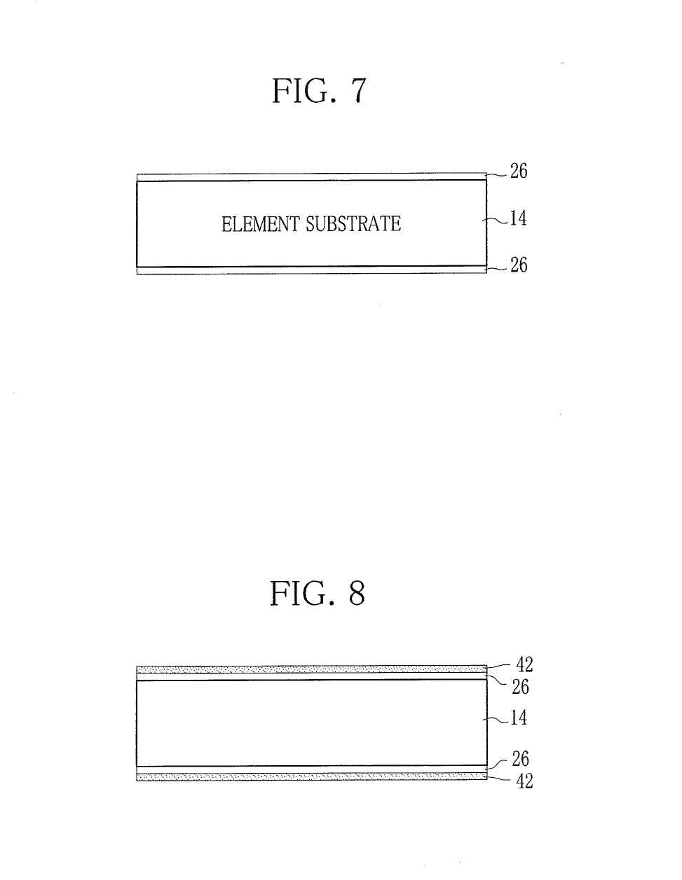

First, as shown in FIG. 7, the insulating layers 26 are formed on both front and back surfaces of the element substrate 14 (insulating layer forming step). The insulating layer 26 is a silicon oxide film (SiO₂) having a thickness of the order of 10 to 50 nm, for example. Although it is not illustrated, antireflection film (SiN or the like) may be provided on the insulating layer 26 formed here, or on the back-surface electrode 15 described later on, or on the insulating layer 27, if necessary. An example without having the antireflection film will be described.

Note that, a both sides polished silicon wafer is used as the element substrate 14. However, a one side polished silicon wafer only one surface of which on the side adhered to a first support substrate 47 as described later is polished, or a substrate on which silicon is grown by epitaxial growth on a surface formed with the PDs 21 and the like may be used instead.

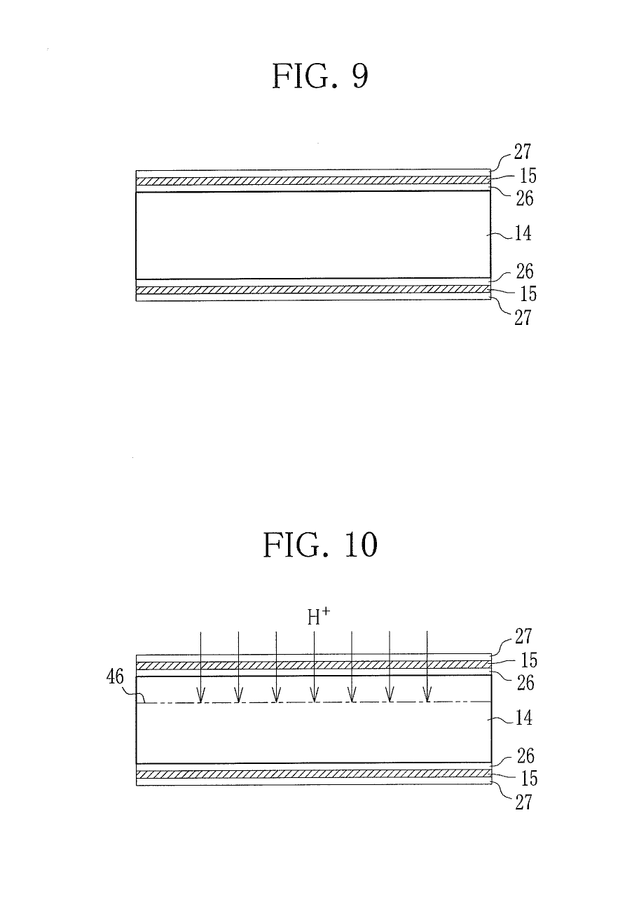

After the insulating layers 26 are formed on the element substrate 14, as shown in FIG. 8, amorphous silicon films 42 doped with an impurity are deposited on the insulating layers 26 (deposition step). The amorphous silicon film 42 is doped with phosphorus (P) as the impurity, and is deposited by a low pressure CVD method. Then, the element substrate 14 having the amorphous silicon films 42 is annealed to form the insulating layer 27 and the back-surface electrode 15, as shown in FIG. 9 (MOS structure forming step). That is to say, the insulating layer 27 is a thermal oxide film (SiO₂) formed by thermal oxidation of the surface of the amorphous silicon film 42. The back-surface electrode 15 is a polycrystalline silicon film into which the amorphous silicon film 42 is polycrystallized by annealing. Therefore, a MOS structure composed of the element substrate 14, the insulating layer 26, and the back-surface electrode 15 is formed at this step on a light irradiation side of the imaging device 10.

After the formation of the MOS structure as described above, hydrogen ions (H⁺) are implanted in the element substrate 14 from one surface thereof, as shown in FIG. 10 (ion implantation step). The hydrogen ions are implanted to the element substrate 14 with such energy that the thickness of a SOI layer formed with the PDs 21 and the like becomes equal to an ion range Rp, so a damaged surface 46 is formed at a predetermined depth. The hydrogen ions are implanted at a concentration of the order of 10¹⁶ cm⁻², for example.

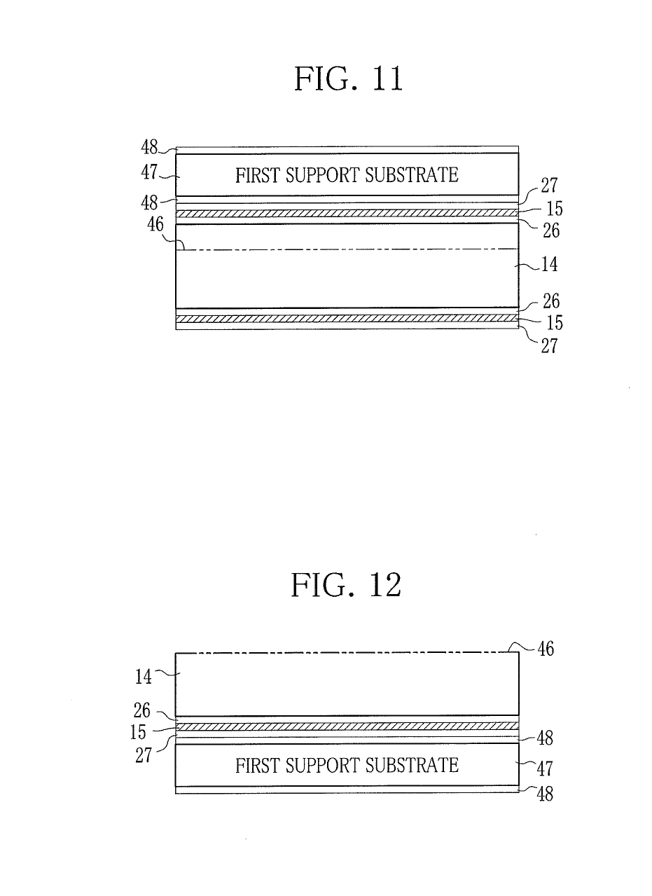

Then, as shown in FIG. 11, the first support substrate 47 is adhered to the surface implanted with the hydrogen ions (first support substrate adhering step). The first support substrate 47 is a silicon wafer formed with thermal oxide films 48 on its surfaces, and is adhered to the element substrate 14 at room temperature (or a temperature at which the first support substrate 47 does not peel off in a later step). After the first support substrate 47 is adhered to the element substrate 14, peripheral margins of the element substrate 14 and the first support substrate 47 are cut away if necessary.

After that, as shown in FIG. 12, a unit of the element substrate 14 and the first support substrate 47 is turned upside down such that the first support substrate 47 is positioned downward, and is subjected to a heat treatment. The element substrate 14 is split by taking advantage of hydrogen brittleness (occurrence of voids) at the damaged surface 46 by the heat treatment (splitting step). The heat treatment is performed in an atmosphere of an inert gas at a temperature of, for example, 500° C. or more. Note that, the element substrate 14 is split at the damaged surface 46 in this embodiment. However, if the same process is performed without implanting the hydrogen ions, the thickness of the element substrate 14 may be adjusted by combining mechanically polishing, wet etching using KOH, TMAH, or the like, chemical polishing (CMP), and the like of the surface of the exposed element substrate 14.

The split element substrate 14 is subjected to another heat treatment (at 1000 to 1300° C., for example) for enhancing the adhesion between the first support substrate 47 and the element substrate 47, and an oxidation and removal process for oxidizing the exposed damaged surface 46 to remove a defect, though it is not illustrated. Also, in order to improve flatness, a surface that was the damaged surface 46 is subjected to a reduction heat treatment using just H₂ or H₂ and Ar.

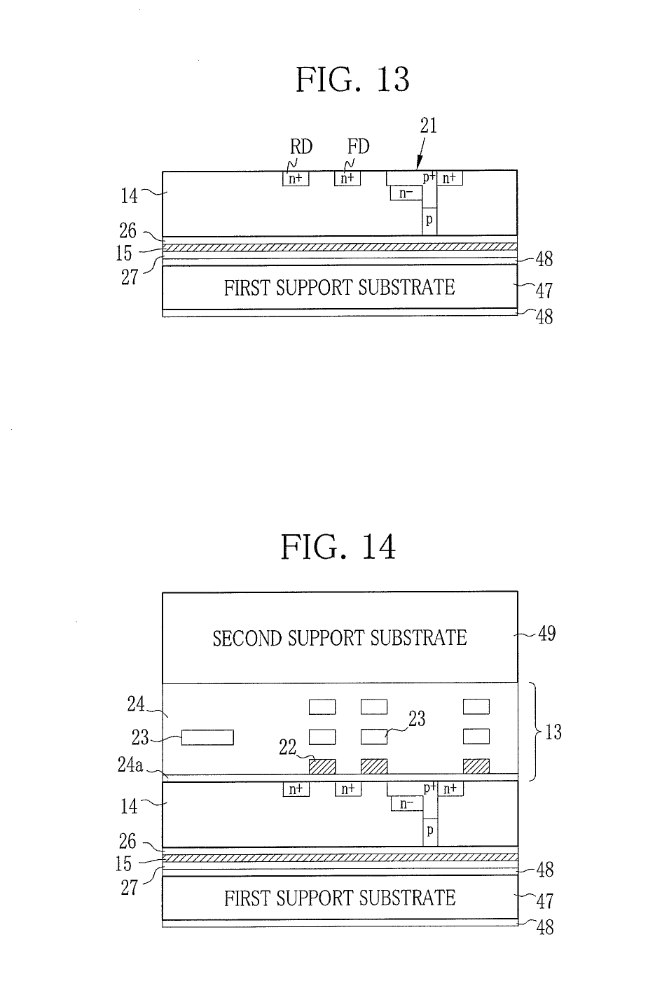

As shown in FIG. 13, the photodiodes (PDs) 21, the floating diffusion regions (FDs), the reset drains (RDs), and the like are formed in the surface of the exposed element substrate 14 (element forming step). Then, as shown in FIG. 14, the gate electrodes 22, the wiring 23, the other circuits, and the like are formed with interposition of the insulating film 24a and the interlayer insulating film 24 in accordance with the photodiodes 21 and the like formed in the element substrate 14 to form the wiring layer 13 (wiring layer forming step). Note that, the structure of the element substrate 14 may be formed after formation of the gate electrodes 22. Then, the surface of the wiring layer 13 is flattened by CMP, and a second support substrate 49 is adhered thereon (second support substrate adhering step). In a processing step on a light incident side, the second support substrate 49 is adhered by contact between flattened surfaces and a heat treatment for enhancing the contact, without using a glue or the like. This is for the purpose of reducing damage due to processing, and preventing the occurrence of a malfunction in a heat treatment at a temperature of the order of 400° C. for stabilizing a contact resistance between metal and metal or between metal and polycrystalline silicon. Note that, the second support substrate 49 is a silicon wafer, for example.

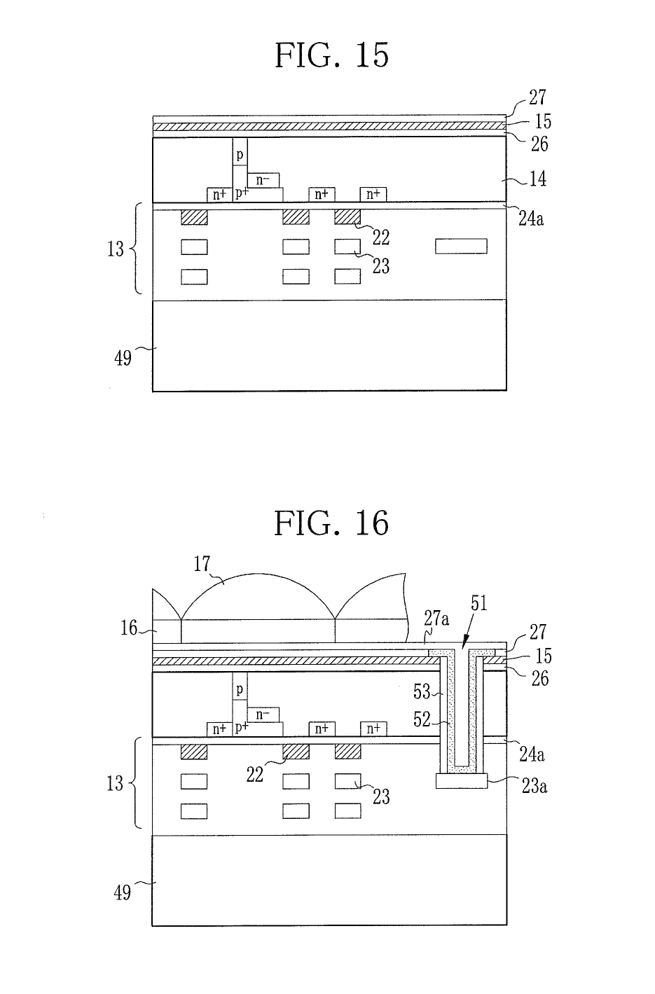

After the adhesion of the second support substrate 49 as described above, the unit is turned upside down again such that the second support substrate 49 is positioned downward, and the first support substrate 47 is removed, as shown in FIG. 15 (first support substrate removing step). For example, the first support substrate 47 is almost removed by mechanical polishing, and completely removed by wet etching. In the wet etching, the thermal oxide film 48 (and the insulating layer 26) is used as an etch stopper.

Then, as shown in FIG. 16, through holes 51 are formed. The back-surface electrode 15 is exposed around the through hole 51 to connect the back-surface electrode 15 to predetermined wiring 23a (wiring connecting step). A voltage is applied to the back-surface electrode 15 through the wiring 23a. A metal thin film 52 such as Cu/TiN, AlCu/TiN, or the like connects the predetermined wiring 23a and the back-surface electrode 15. An insulating film 53 provided on an interior surface of the through hole 51 prevents shorting of the element substrate 14 and the metal thin film 52. After that, an insulating film 27a is provided so as not to expose the metal thin film 52, and the color filter 16 and the microlenses 17 are formed thereon in accordance with an arrangement of the photodiodes 21 to form the imaging device 10 (color filter forming step and microlens forming step).

As described above, in the imaging device 10, the MOS structure, which is composed of the silicon of the element substrate 14, the insulating layer 26, and the back-surface electrode 15, is formed before the formation of the elements such as the photodiodes 21 formed in an embedded manner in the element substrate 14 and the formation of the wiring layer 13 including a signal readout circuit and the like. Although formation of a thermal oxide film of high quality requires a high temperature heat treatment of approximately 800 to 900° C., subjecting the metal thin film formed in the wiring layer 13 to the high temperature heat treatment causes contamination of an element due to metal diffusion, damage of a contact portion, melting of silicon into metal, and the like and results in damaging the element. Therefore, manufacturing the imaging device 10 as described above allows compatibility between the MOS structure using a thermal oxide film (insulating layer 26) of high quality and the formation of the photodiodes 21, the other circuits, and the like.

### Second Embodiment

The first embodiment describes an example in which the back-surface electrode 15 is provided uniformly on all the pixels 31. However, the back-surface electrode 15 may be constituted of a plurality of separate electrodes. This structure is suitable particularly for an imaging device that takes an image having a horizontal (or vertical) parallax using a pair of pixels 31 as a unit in order to obtain a stereoscopic image (so-called 3D image) or realize a phase difference AF.

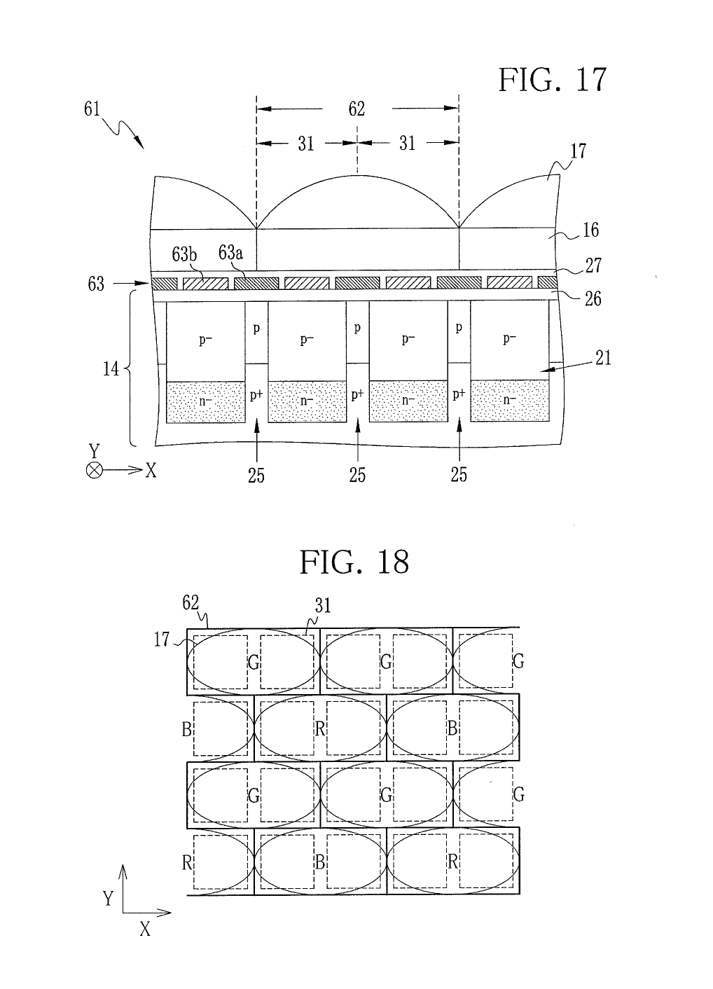

As shown in FIG. 17, the two pixels 31 are united as a pixel pair 62 in an imaging device 61. The color filter 16 is provided such that one color segment corresponds to the one pixel pair 62. Also, the one microlens 17 is provided for each pixel pair 62.

Note that, although it is omitted in FIG. 17 for the sake of simplification, the wiring layer 13 and the like are provided under the element substrate 14 (on the side of a front surface) as with the imaging device 10 of the first embodiment described above. Also, the element substrate 14 is provided with the floating diffusion regions and the reset drains in addition to the photodiodes 21, as with the above embodiment. FIG. 17 shows a cross-sectional view taken in a row direction (X direction), in which the floating diffusion regions and the reset drains are not seen.

The imaging device 61 has the back-surface electrode 63 formed on the insulating layer 26 in the back surface being on the light incident side. The back-surface electrode 63 is a transparent electrode provided on the insulating layer 26 on the back surface of the element substrate 14, and includes two types of electrodes, i.e. first electrodes 63a and second electrodes 63b. The first electrodes 63a and the second electrodes 63b are made of polycrystalline silicon or an ITO film, for example.

A formation method of the back-surface electrodes 63a and 63b will be briefly described. In the case of making the back-surface electrodes 63a and 63b of the polycrystalline silicon, the first support substrate 47 is removed in the first support substrate removing step (see FIG. 15), and the insulating layer 27 is exposed. After the first support substrate removing step, the insulating layer 27 and the back-surface electrode (polycrystalline silicon transparent electrode) 15 are processed by lithography and anisotropic dry etching to form the desired first and second electrodes 63a and 63b. In the case of making the back-surface electrodes 63a and 63b of the ITO film, the first support substrate removing step is performed so as to leave the gate insulating layer 26, and then the ITO film is formed by sputtering or the like at a low temperature of 400° C. or less. After that, the desired back-surface electrodes 63a and 63b can be formed by lithography and anisotropic dry etching. The lithography and the anisotropic dry etching are performed in the same manner as the case of the polycrystalline silicon. Note that, in the case of making the back-surface electrodes 63a and 63b of the ITO film, the deposition step (see FIG. 8) and the MOS structure forming step (see FIG. 9), which form the back-surface electrode 15 in the first embodiment, may not be carried out. In the case of making the back-surface electrodes 63a and 63b of the ITO film, a step of sputtering the ITO film as described above corresponds to the MOS structure forming step.

The first electrode 63a is disposed on the element separation region 25, which partitions the photodiode 21 of each pixel 31. The second electrode 63b is disposed on the photodiode 21 (between the element separation regions 25) of each pixel 31. The insulating layer 27 insulates the first electrodes 63a and the second electrodes 63b.

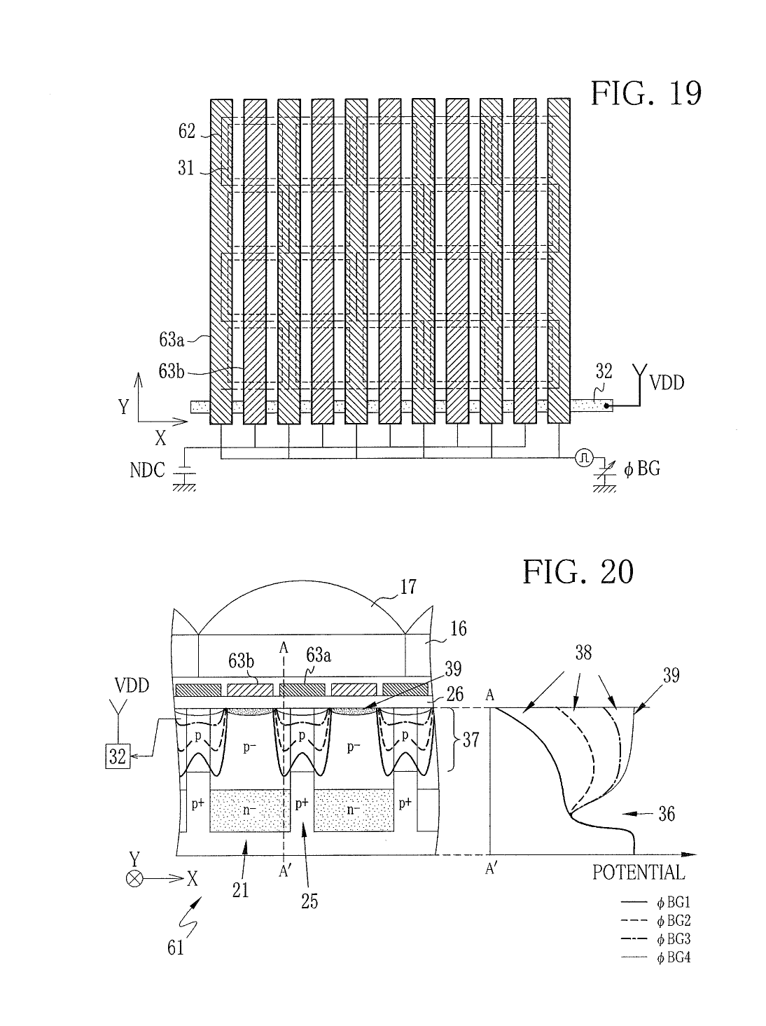

As shown in FIG. 18, when the pixels 31 are arranged in a lattice pattern and the pixel pairs 62 are set in a staggered manner by one pixel every one row, as shown in FIG. 19, the first electrodes 63a and the second electrodes 63b are alternately arranged in stripes along a column direction (Y direction) with little gaps therebetween. Also, as with the imaging device 10 of the first embodiment, the imaging device 61 is provided with n+ diffusion layer 32, being the electric charge discharging path, next to the pixel section having an array of the pixels 31. Both the first and second electrodes 63a and 63b are overlaid on the n+ diffusion layer 32.

In the imaging device 61, a variable voltage φBG is applied in a pulse form to the first electrodes 63a disposed on the element separation regions 25 in accordance with operation timing of the imaging device 61 and the like. A predetermined negative voltage NDC is applied to the second electrodes 63b disposed on the photodiodes 21.

As shown in FIG. 20, in the imaging device 61, a potential in the silicon-insulating layer interface 37 in the vicinity of the element separation regions 25 varies in accordance with the variable voltages φBG1 to φBG4 to be applied to the first electrodes 63a disposed on the element separation regions 25. Upon applying one of the positive voltages φBG1 to φBG3 (φBG1>φBG2>φBG3) to the first electrode 63a, the electron inversion layer 38 is formed in the silicon-insulating layer interface 37 in the vicinity of the element separation region 25.

The depth and the like of the electron inversion layer 38 formed here depend on the magnitude of the positive voltage φBG1 to φBG3 to be applied. For example, upon applying the positive voltage φBG1, the electron inversion layer 38 is formed so as to be coupled to the accumulation layer 36 of the photodiode 21, and the electric charge is discharged through the electron inversion layer 38 to the n+ diffusion layer 32. Upon applying the positive voltage φBG2 or φBG3 that is lower than the positive voltage φBG1, the electron inversion layer 38 is separated from the accumulation layer 36. In the case of applying a positive voltage to the first electrode 63a within a range less than the positive voltage φBG1, the electron inversion layer 38 formed under the first electrode 63a expands to a width direction (X direction) and a depth direction with increase in the magnitude of the applied voltage. Upon applying the negative voltage φBG4 to the first electrode 63a, the hole accumulation layer 39 is formed in the silicon-insulating layer interface 37 in the vicinity of the element separation region 25.

The predetermined negative voltage NDC is applied to the second electrode 63b. Thus, the predetermined hole accumulation layer 39 is always formed in the silicon-insulating layer interface 37 on the photodiode 21.

The operation of the imaging device 61 structure above is as follows. In the case of obtaining a pair of images (3D image) having a horizontal (or vertical) parallax using the pixel pairs 62, for example, the positive voltage φBG3 (or φBG2) is applied to the first electrodes 63a in the accumulation period for accumulating signal charge and the readout period of the signal charge. Thus, the photodiode 21 having the second electrode 63b thereon to which the negative voltage NDC is applied has maximum sensitivity in the vicinity of its middle, and almost all incident light is converted into the signal charge. At the same time, the electron inversion layer 38 is formed in the vicinity of the element separation region 25 having the first electrode 63a thereon, so the signal charge that has occurred in the electron conversion layer 38 is discharged to the n+ diffusion layer 32 upon its occurrence without flowing into the photodiode 21. This is equal to that an effective photoelectric conversion region of each pixel 31 is narrowed from the side of the element separation regions 25 in accordance with the positive voltage φBG3 applied to the first electrodes 63a. Therefore, out of light incident upon the left and right pixels 31 of the pixel pair 62, the incident angle of light to be converted into the signal charge becomes large (sensitivity to light incident more obliquely is relatively increased), and hence a parallax angle becomes large. Thus, applying the positive voltage φBG3 (φBG2) to the first electrodes 63a while applying the negative voltage NDC to the second electrodes 63b, as described above, makes it possible to control the parallax angle of monocular 3D or phase difference AF in an imaging signal obtained by each of the left and right pixels 31 of the pixel pair 62 by using an application voltage of the first electrodes 63a.

Just as with the imaging device 10 of the first embodiment, when the intensity of incident light is too high, excessive signal charge flowing over the accumulation layer 36 is discharged from the electron inversion layer 38 formed by the first electrode 63a to the n+ diffusion layer 32 without flowing into the accumulation layer 36 of another pixel 31.

In the imaging device 61, the positive voltage φBG1 is applied to the first electrodes 63a in the reset period. Thus, since the electron inversion layer 38 is coupled to the accumulation layer 36 in the reset period, unnecessary electric charge is discharged just as with the imaging device 10 of the above first embodiment. Also, as with the first embodiment, the alternate application of the positive voltage φBG1 and the negative voltage φBG4 to the first electrodes 63a in the reset period further expedites the discharge of the electric charge.

Note that, an example of applying the positive voltage φBG3 (φBG2) to the first electrodes 63 in the accumulation period and the readout period to further increase the parallax angle was described here, but is not limited to this. For example, in the accumulation period and the readout period, the negative voltage φBG4 may be applied to the first electrodes 63a. In this case, since the hole accumulation layer 39 is formed in the entire silicon-insulating layer interface 37, holes attracted to the hole accumulation layer 39 are recombined with dark current occurring in the silicon-insulating layer interface 37 and the like. This makes it possible to expand the accumulation layer 36 with reducing noise and facilitates high sensitivity imaging.

The imaging device 61 may be switchable between two modes, that is, a mode of increasing the parallax angle between the left and right pixels 31 by applying a positive voltage φBG (<φBG1) to the first electrodes 63a for obtaining the 3D image and performing the phase difference AF, and a mode of the high sensitivity imaging by applying the negative voltage φBG4 to the first electrodes 63a for obtaining a normal 2D image.

Note that, the above second embodiment describes an example of applying the constant negative voltage to the second electrodes 63b, but a voltage to be applied to the second electrodes 63b may be variable. However, a voltage is applicable independently to each of the first electrodes 63a and the second electrodes 63b. In this case, for example, a positive voltage is applied to the first electrodes 63a and a negative voltage is applied to the second electrodes 63b in the accumulation period and the readout period to carry out the same operation as the above second embodiment, and the positive voltage φBG1 is applied to the second electrodes 63b too in the reset period for the purpose of further facilitating discharge of unnecessary electric charge.

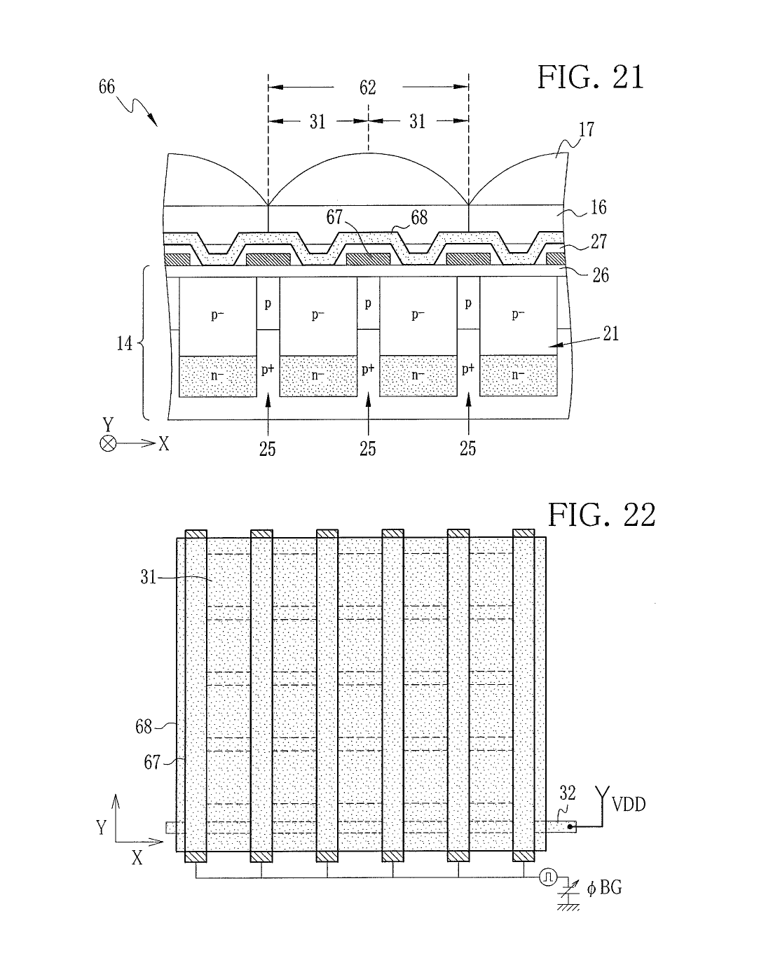

In the above second embodiment, the second electrodes 63b are transparent electrodes just as with the first electrodes 63a, but are not limited thereto. For example, as shown in an imaging device 66 of FIGS. 21 and 22, a back-surface electrode constituted of back-surface electrodes 67 and a ferroelectric thin film 68 may be provided instead of the back-surface electrodes 63a and 63b of the second embodiment.

The back-surface electrodes 67 are transparent electrodes made of polycrystalline silicon or the like, just as with the first electrodes 63a of the above imaging device 61, and disposed on the element separation regions 25. The back-surface electrodes 67 extend so as to overlay at least the n+ diffusion layer 32, and a variable voltage φBG (φBG1 to φBG4) is applied in a pulse form.

The ferroelectric thin film 68 is a transparent thin film made of HfO₂ or the like, and disposed so as to cover the back-surface electrodes 67. The ferroelectric thin film 68 is processed by a heat treatment such that a side of the element substrate 14 is polarized positively (+) and a side of the back surface of the imaging device 66 being the light incident side is polarized negatively (−). Thus, the ferroelectric thin film 68 forms in the silicon-insulating layer interface 37 the same potential as that formed by an electrode to which a constant voltage is always applied. The heat treatment applied to the ferroelectric thin film 68 is a low temperature heat treatment of 400° C. or less, for example, to process crystallization of HfO₂. The crystallization of HfO₂ polarizes the ferroelectric thin film 68.

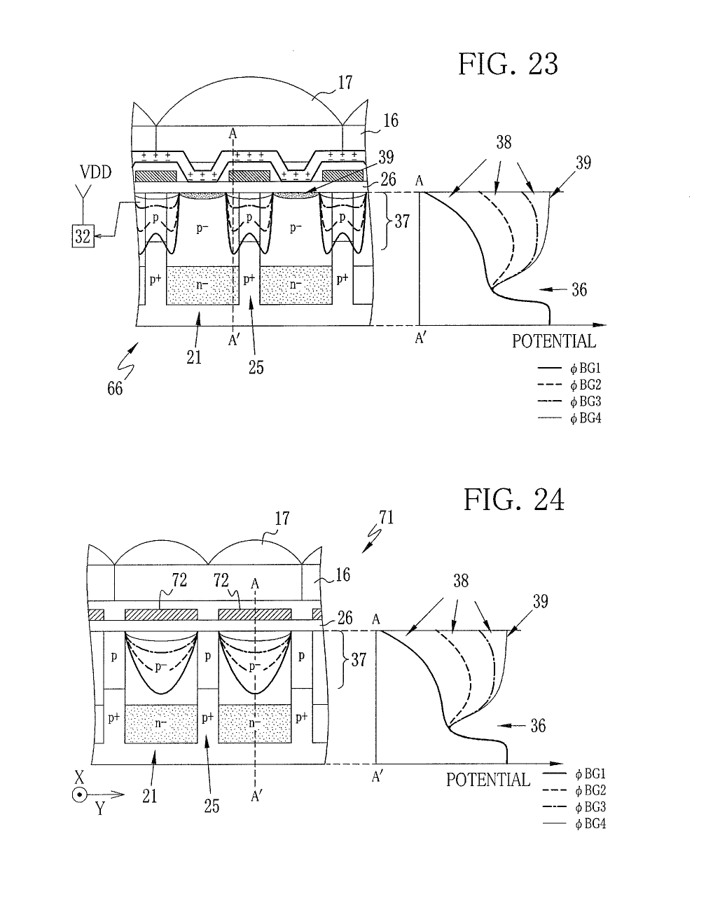

In the imaging device 66 structured as above, as shown in FIG. 23, the positive voltage φBG2 or φBG3 (<φBG1) is applied to the back-surface electrodes 67 in the accumulation period and the readout period, and the positive voltage φBG1 is applied to the back-surface electrodes 67 in the reset operation. Thereby, the imaging device 66 functions in a like manner as the imaging device 61 of the above second embodiment.

Note that, an example of using the ferroelectric thin film 68 was described here, but a dielectric thin film (silicon nitride or the like) implanted with bound electrons by irradiation with an ultraviolet ray, application of an electric field, ion implantation, or the like may be used instead of the ferroelectric thin film 68.

### Third Embodiment

The above second embodiment describes an example of providing the back-surface electrodes 63a and 63b in stripes along the column direction (Y direction). In a third embodiment to be hereinafter described, separate back-surface electrodes are provided dividedly in stripes along a row direction (X direction).

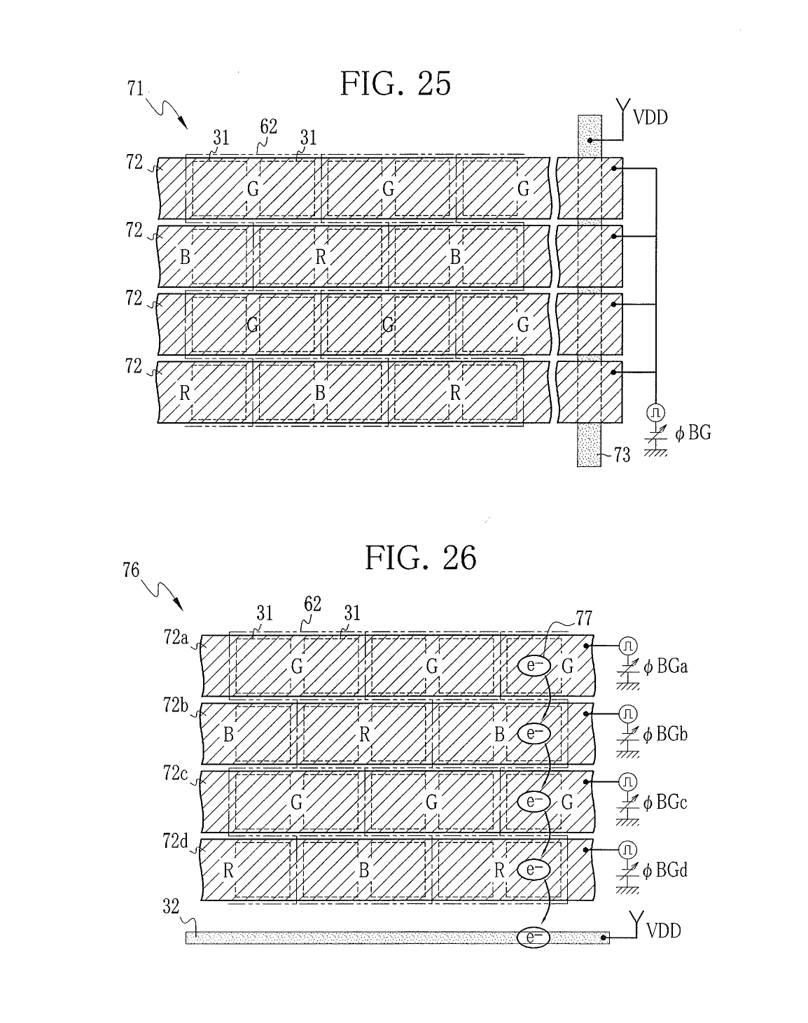

As shown in FIGS. 24 and 25, an imaging device 71 has back-surface electrodes 72 that are provided dividedly in stripes along the row direction of the pixels 31. The back-surface electrodes 72 are transparent electrodes made of polycrystalline silicon or an ITO film, and disposed on the photodiodes 21 so as to cover almost the entire photoelectric conversion region. The imaging device 71 also includes an n+ diffusion layer 73 elongated along the column direction (Y direction) of the pixels 31 next to the pixel section having an array of the pixels 31. The n+ diffusion layer 73 is connected to the power voltage VDD and functions as an electric charge discharging path. The back-surface electrodes 72 extend from an area above the pixel section to an area above the n+ diffusion layer 73. The variable voltage φBG (φBG1 to φBG4) is applied to the back-surface electrodes 72 in accordance with operation timing of the imaging device 71.

For example, upon applying the positive voltage φBG3 (or φBG2) to the back-surface electrode 72, the electron inversion layer 38 is formed in the silicon-insulating layer interface 37 separately from the accumulation layer 36. Upon applying the positive voltage φBG1, the electron inversion layer 38 is formed so as to be coupled to the accumulation layer 36. Upon applying the negative voltage φBG4, the hole accumulation layer 39 is formed in the silicon-insulating layer interface 37.

In the imaging device 71 as structured above, applying the positive voltage φBG3 or φBG2 (<φBG1) in the accumulation period and the readout period makes it possible to discharge through the electron inversion layer 38 to the n+ diffusion layer 73 the dark current occurring in the silicon-insulating layer interface 37 and the excessive signal charge overflowing the accumulation layer 36. Also, by applying the positive voltage φBG1 to the back-surface electrodes 72 in the reset period, the imaging device 71 discharges the unnecessary electric charge to the n+ diffusion layer 73 through the electron inversion layer 38.

Note that, an example of applying an uniform voltage φBG (φBG1 to φBG4) to all the back-surface electrodes 72 that are provided on a row-by-row basis was described here, but is not limited thereto. For example, in an imaging device 76 shown in FIG. 26, variable voltages φBGa to φBGd may be applied individually to each of the back-surface electrodes 72a and 72d provided on a row-by-row basis. In this case, the n+ diffusion layer 32 disposed along the row direction (X direction) is provided, instead of the n+ diffusion layer 73 disposed along the column direction (Y direction).

In this structure, a CCD (hereinafter called back-surface CCD) that is driven by control of the depths of the electron inversion layers 38 using the back-surface electrodes 72a to 72d is formed in a back-surface of the imaging device 76. In other words, since each of the back-surface electrodes 72a to 72d is not connected to the n+ diffusion layer being the electric charge discharging path, unnecessary electric charge that has occurred in each pixel 31 is accumulated in the electron inversion layer 38. By periodically varying each of the voltages φBGa to φBGd to be applied to each of the back-surface electrodes 72a to 72d so as to sequentially shifting the depths of the electron inversion layers 38 along the column direction, the electric charge 77 accumulated in the electron inversion layer 38 is transferred in the column direction. Accordingly, it is possible to discharge the electric charge 77 accumulated in the electron inversion layer 38 to the n+ diffusion layer 32.

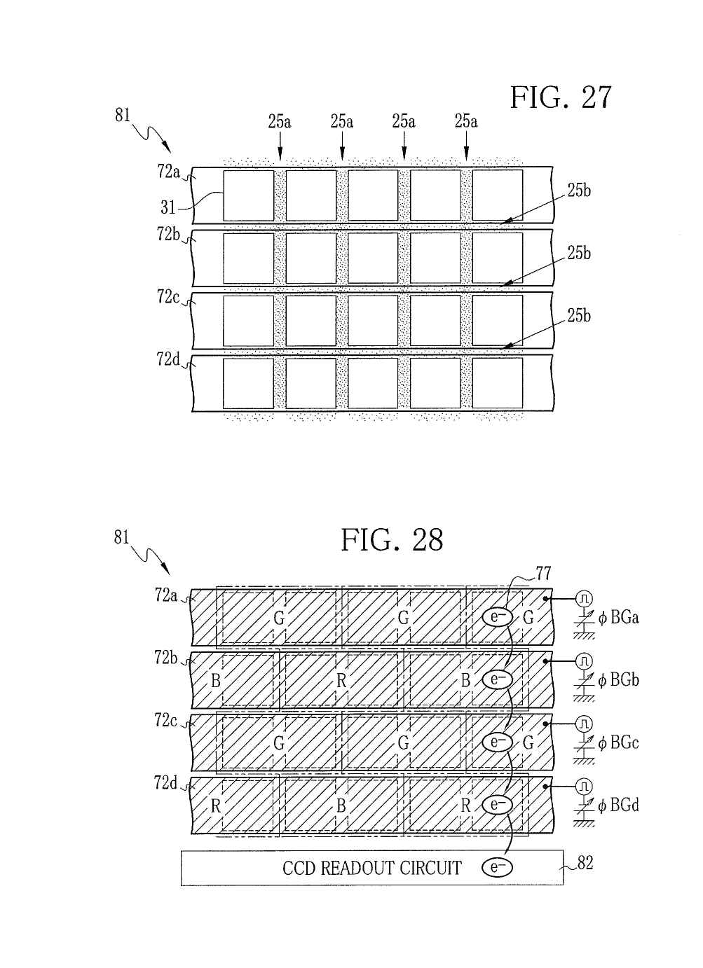

In the case of forming the back-surface CCD as described above, since the element separation region 25 of each pixel 31 is made of the p layer in the vicinity of the silicon-insulating layer interface 37, application of the positive voltage φBG1 to φBG3 to each of the back-surface electrodes 72a to 72d integrates electric charge discharged from each row. However, in an imaging device 81 shown in FIG. 27, element separation regions 25a between columns of the pixels 31 are formed of a p+ layer, and element separation regions 25b between rows of the pixels 31 are formed of a p layer. Thus, it is possible to accumulate electric charge discharged from each pixel 31 in the electron inversion layer 38 separately from column to column.

In a case where electric charge of each pixel 31 can be separated in the back-surface CCD as described above, as shown in FIG. 28, a circuit for reading the CCD (hereinafter called CCD readout circuit) 82 constituted of a horizontal CCD and the like is provided in a lowermost row. Applying the positive voltage φBGa to φBGd to each of the back-surface electrodes 72a to 72d and transferring the electric charge 77 to the CCD readout circuit 82 make it possible to read out the signal charge of each pixel 31. In other words, formation of the back-surface CCD that can separately read out the electric charge 77 of each pixel 31 allows not only reading out the signal charge through the wiring layer formed on the front surface side, but also reading out the signal charge through the back-surface CCD.

For example, the signal charge of the R pixels and B pixels having the back-surface electrodes 72b and 72d may be read out by a CMOS circuit (wiring layer 13) on the front surface side, and the signal charge of the G pixels having the back-surface electrodes 72a and 72c may be read out by the back-surface CCD. In this case, the signal charge of the G pixel under the back-surface electrode 72a and the signal charge of the G pixel under the back-surface electrode 72c are added in reading out the signal charge of the G pixels by the back-surface CCD. This improves an S/N ratio, as compared with the case of reading out and adding the signals of the G pixels by the CMOS circuit.

Thus, the imaging device 81 can read out the signal charge with the combined use of the front-surface CMOS circuit and the back-surface CCD if mixture of pixels is required, and can switch its operation such that the back-surface CCD discharges the unnecessary electric charge if the mixture of pixels is not required.

Note that, since a CMOS imaging device conventionally reads out its signals on a row-by-row basis, an example of providing the back-surface electrodes on a row-by-row basis and transferring the signal charge by the back-surface CCD constituted of the back-surface electrodes was described above. However, in the case of reading out the signals on a column-by-column basis, providing the back-surface electrodes on a column-by-column basis allows the same operation as above. In a modification example of the third embodiment described above, the back-surface CCD is controlled by the back-surface electrodes 72a and 72d with four-phase drive, but may be with three-phase drive.

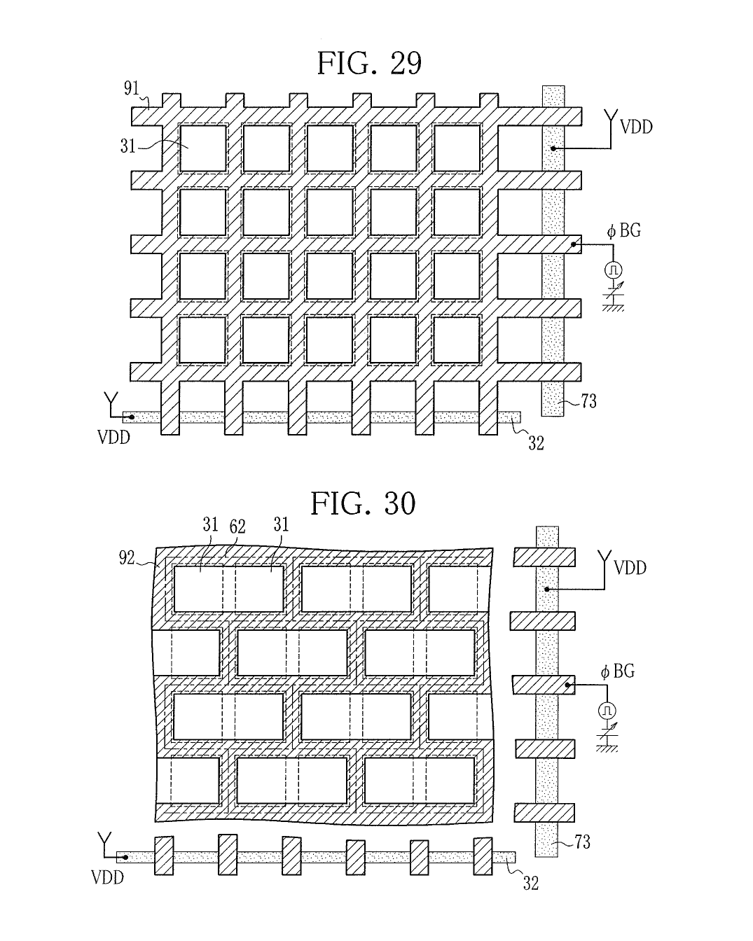

In the above second and third embodiments, the back-surface electrodes are arranged in the column direction or the row direction, but are not limited thereto. For example, as shown in FIG. 29, a back-surface electrode 91 in a lattice shape may be provided, which is overlaid on the element separation region 25 and opened in the portions of the pixels 31 so as to enclose each pixel 31. In this case, one of the n+ diffusion layer 32 extending in the row direction and the n+ diffusion layer 73 extending in the column direction is provided in the periphery of the pixels 31. Also, the back-surface electrode 91 is overlaid on at least one of the n+ diffusion layer 32 and the n+ diffusion layer 73, and the variable voltage φBG is applied thereto. Therefore, in the accumulation period, it is possible to increase a signal amount based on a parallax between the pixels 31, while the excessive signal charge, which occurs due to the incident light of too high intensity, is discharged to the n+ diffusion layer 32 (or the n+ diffusion layer 73) through the electron inversion layer 38 formed in the vicinity of the element separation region 25 just as with the above second embodiment. At the same time, in the reset period, the formation of the electron inversion layer 38 facilitates discharging the unnecessary electric charge. Furthermore, although it is not illustrated, if the ferroelectric thin film is provided just as with the second embodiment, the formation of the hole accumulation layer 39 in the silicon-insulating layer interface 37 on each photodiode 21 facilitates removing noise such as dark current occurring in the interface.

FIG. 29 shows an example of the imaging device in which each pixel 31 is used individually, but as with the imaging device described in the second and third embodiments, the imaging device may have the pixel pairs 62 each of which is composed of a pair of the pixels 31. In this case, the back-surface electrode 91 in a lattice shape (net shape) may be provided so as to enclose all the pixels 31 as described above, or the back-surface electrode 92 in a lattice shape (net shape) that encloses each pixel pair 62 may be provided as shown in FIG. 30.

When using the back-surface electrode 91, 92 in a lattice shape (or net shape), in the case of increasing the separability of each individual pixel 31, the back-surface electrode 91, 92 is not necessarily the transparent electrode, but may be made of a light shielding material. In the case of making the back-surface electrode 91, 92 out of the light shielding material, for example, a TiN/Ti film or a TiN film is preferably used if a thin film structure is required. If a low resistance is important, tungsten or aluminum film is preferably used.

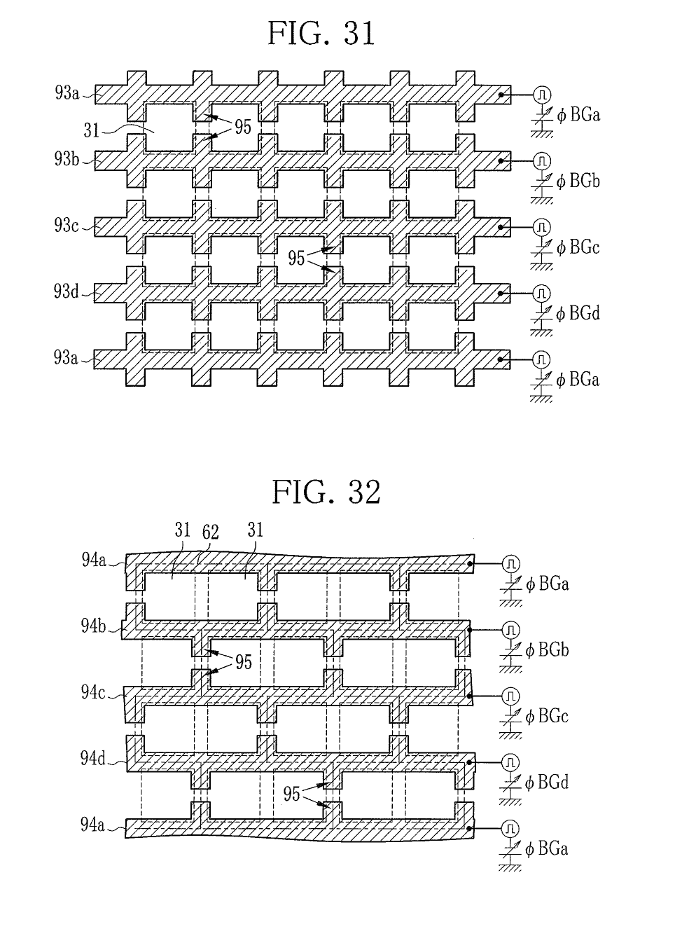

Note that, an example of the back-surface electrode 91, 92 that is integrated in a lattice shape or a net shape in the column and row directions of the pixels 31 is described here, but the separability between the pixels 31 or between the pixel pairs 62 can be increased even if the back-surface electrode of every row or column is not coupled. For example, as shown in FIGS. 31 and 32, using back-surface electrodes 93a to 93d, 94a to 94d that have protrusions 95 disposed along the row direction so as to shade gaps between the columns of the pixels 31 allows obtainment of almost the same separability of the pixels 31 (pixel pairs 62) as described above.

In this case, each of the back-surface electrodes 93a to 93d, 94a to 94d extends to an area above the n+ diffusion layer 73, so the electron inversion layer 38 formed by each of the back-surface electrodes 93a to 93d, 94a to 94d is coupled to the n+ diffusion layer 73, though illustration is omitted. To each of the back-surface electrodes 93a to 93d, 94a to 94d, variable voltages φBGa to φBGd may be independently applied, or a variable voltage φBG may be uniformly applied. Also, FIGS. 31 and 32 show an example of providing the protrusions 95 in the column direction of the back-surface electrodes extending in the row direction, but protrusions may be provided in the row direction of back-surface electrodes extending in the column direction.

Note that, the back-surface electrode is provided in the pixel section having an array of the pixels 31 and the n+ diffusion layer 32, 73 in the above first to third embodiments, but the back-surface electrode may be provided in an area other than the pixel section.

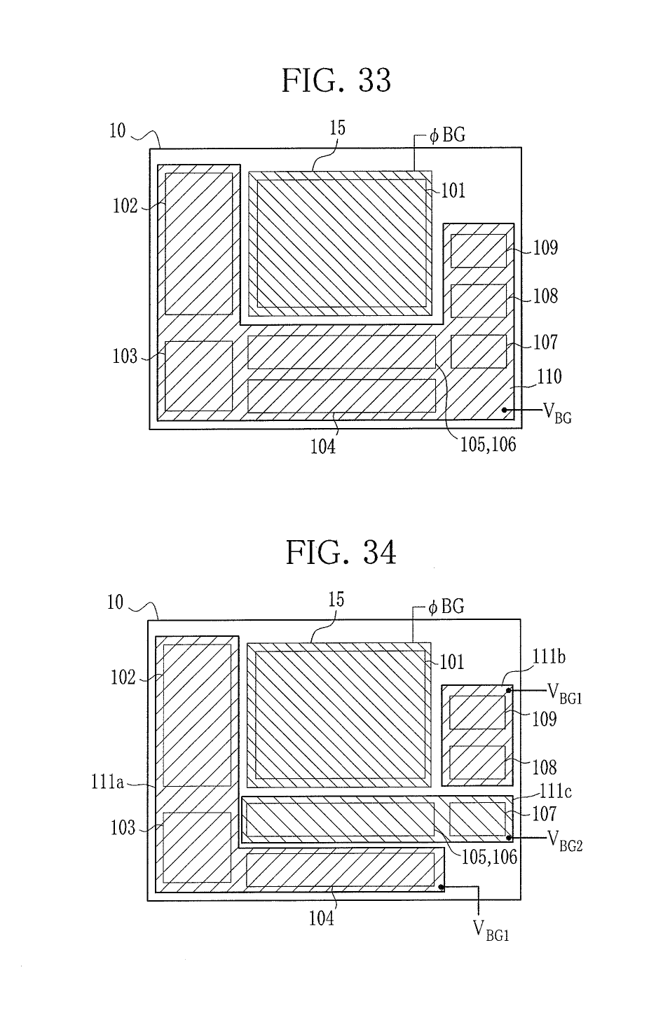

For example, as shown in FIG. 33, the imaging device 10 is provided with various circuits including a vertical selection circuit 102, a timing generator (TG) 103, a horizontal selection circuit 104, a sample holder (S/H) 105, a correlated double sampling circuit (CDS) 106, an automatic gain controller (AGC) 107, a digital-to-analog converter (A/D) 108, a digital amplifier (AMP) 109, and the like around its pixel section 101.

For example, the above first embodiment describes an example of providing the back-surface electrode 15 on the pixel section 101, but as shown in FIG. 33, it is preferable that a back-surface electrode 110 is also provided on the peripheral circuits 102 to 109 and the like. A voltage is applicable to the back-surface electrode 110 independently of the back-surface electrode 15 provided on the pixel section 101. Providing the back-surface electrode 110 on the peripheral circuits 102 to 109 and the like and applying a predetermined voltage V_{BC} thereto facilitates stable operation of each of the peripheral circuits 102 to 109 and the like by blocking noise occurring in the peripheral circuits 102 to 109 or blocking the peripheral circuits 102 to 109 and the like from noise occurring in the pixel section 101. Therefore, it is possible to further easily obtain an image having an improved S/N ratio.

The voltage V_{BC} to be applied to the back-surface electrode 110 provided on the peripheral circuits 102 to 109 is either of positive and negative voltages. Alternatively, the back-surface electrode 110 may be grounded (V_{BC}=GND). Upon applying a positive voltage to the back-surface electrode 110 provided on the peripheral circuits 102 to 109 and the like, the electron inversion layer 38 formed in the silicon-insulating layer interface 37 and the back-surface electrode 110 block (absorb) noise occurring in each of the peripheral circuits 102 to 109 and the like. Upon applying a negative voltage to the back-surface electrode 110 provided on the peripheral circuits 102 to 109 and the like, the hole accumulation layer 39 formed in the silicon-insulating layer interface 37 and the back-surface electrode 110 block (absorb) noise occurring in each of the peripheral circuits 102 to 109 and the like. In the case of grounding the back-surface electrode 110 provided on the peripheral circuits 102 to 109 and the like, the back-surface electrode 110 blocks noise occurring in each of the peripheral circuit 102 and 109 and the like.

FIG. 33 explains an example of uniformly providing one back-surface electrode 110 on the peripheral circuits 102 to 109 and the like, but the example is not limited thereto. For example, as shown in FIG. 34, an analog circuit is preferably provided with a back-surface electrode, and a digital circuit is preferably provided with another. For example, the analog circuit includes the vertical selection circuit 102, the TG 103, the horizontal selection circuit 104, the A/D 108, and the AMP 109. The analog circuit includes the S/H 105, the CDS 106, and the AGC 107. Thus, for example, a back-surface electrode 111a is provided so as to cover the vertical selection circuit 102, the TG 103, and the horizontal selection circuit 104. A back-surface electrode 111b is provided so as to cover the A/D 108 and the AMP 109. A back-surface electrode 111c is provided so as to cover the S/H 105, the CDS 106, and the AGC 107. The back-surface electrodes 111a and 111b are applied with a voltage V_{BC1}, and the back-surface electrode 111c is applied with a voltage V_{BC2}. The voltages V_{BC1} and V_{BC2} may be either of positive and negative voltages or grounded. The voltages V_{BC1} and V_{BC2} may be equal or different. Providing the back-surface electrodes separately to the digital circuit and the analog circuit makes it possible to certainly prevent noise occurring in the analog circuit from flowing into the digital circuit through the electron inversion layer 38 and the hole accumulation layer 39, or noise occurring in the digital circuit from flowing into the analog circuit, and hence an image having an improved S/N ratio can be obtained. In particular, noise is hard to remove from the analog circuit, so preventing a flow of the noise that has occurred in the digital circuit into the analog circuit is effective at improving the S/N ratio.

Note that, there are provided the two back-surface electrodes 111a and 111b in FIG. 34, because the digital circuits are disposed in two separate areas. However, if the digital circuits are gathered in one area, one back-surface electrode may be provided for all the digital circuits.

Note that, a manufacturing method of the imaging devices according to the above second and third embodiments is the same as that described in the first embodiment, except that a patterning step of the back-surface electrode and a deposition step of a ferroelectric and the like are added.

Note that, the above first embodiment described an example of a honeycomb pixel arrangement, and the second and third embodiments described an example of a tetragonal lattice-shaped pixel arrangement. However, the arrangement of the pixels is arbitrary, and the present invention is preferably applicable irrespective of the arrangement of the pixels.

Note that, the above first to third embodiments take the back-surface irradiation type CMOS imaging device as an example, but the present invention is preferably applicable to a back-surface irradiation type CCD imaging device too.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. A solid-state imaging device comprising:
an element substrate formed with a plurality of photodiodes each for producing signal charge in accordance with an amount of incident light and accumulating said signal charge, a wiring layer for controlling said photodiodes being formed on a front surface of said element substrate, and said light being incident upon said photodiodes from a back surface of said element substrate;
a back-surface electrode provided on said back surface of said element substrate, for modulating a potential in the vicinity of said back surface of said element substrate by being applied with a voltage in accordance with timing of operation control of said photodiode; and
an electric charge discharging path provided in said element substrate, for discharging electric charge that has flowed into an electron inversion layer, when said electron inversion layer formed in the vicinity of said back surface of said element substrate upon applying a positive voltage to said back-surface electrode is coupled to a region for accumulating said signal charge through a monotonously changing potential gradient.

2. The solid-state imaging device according to claim 1, wherein said back-surface electrode is applied with a positive voltage in an accumulation period in which said photodiode accumulates said signal charge upon receiving incidence of said light, and said electron inversion layer is formed in the vicinity of said back surface of said element substrate separately from an accumulation region in which said photodiode accumulates said signal charge.

3. The solid-state imaging device according to claim 1, wherein said back-surface electrode is applied with a negative voltage in an accumulation period in which said photodiode accumulates said signal charge upon receiving incidence of said light, so that a hole accumulation layer is formed in the vicinity of said back surface of said element substrate.

4. The solid-state imaging device according to claim 1, wherein said back-surface electrode is applied with a positive voltage in a reset period for abandoning said signal charge, so that said electron inversion layer is formed in the vicinity of said back surface of said element substrate so as to be coupled to an accumulation region in which said photodiode accumulates said signal charge.

5. The solid-state imaging device according to claim 1, wherein said back-surface electrode is applied alternately with a positive voltage and a negative voltage in a reset period for abandoning said signal charge.

6. The solid-state imaging device according to claim 1, wherein said back-surface electrode is provided uniformly so as to cover said plurality of photodiodes.

7. The solid-state imaging device according to claim 1, wherein
said back-surface electrode includes a first electrode disposed on an element separation region for partitioning said plurality of photodiodes and a second electrode disposed on each of said photodiodes;
said first electrode is used for modulating a potential in the vicinity of said element separation region in accordance with an operation of said photodiode by being applied with a voltage in accordance with said operation of said photodiode; and
said second electrode is used for forming a hole accumulation layer in the vicinity of said back surface on said photodiode.

8. The solid-state imaging device according to claim 7, wherein said hole accumulation layer is formed in the vicinity of said back surface on said photodiode by applying a negative voltage to said second electrode.

9. The solid-state imaging device according to claim 7, said second electrode is made of a ferroelectric thin film, and said hole accumulation layer is formed in the vicinity of said back surface on said photodiode by polarizing said ferroelectric thin film.

10. The solid-state imaging device according to claim 7, wherein said second electrode is a thin film injected with fixed charge, and said fixed charge forms said hole accumulation layer in the vicinity of said back surface on said photodiode.

11. The solid-state imaging device according to claim 7, said first and second electrodes are provided along a column direction of an array of said photodiodes.

12. The solid-state imaging device according to claim 1, wherein said back-surface electrode includes a plurality of individual electrodes provided on a row-by-row basis of said photodiodes, and a voltage is applied to each of said individual electrodes.

13. The solid-state imaging device according to claim 12, wherein by adjusting a voltage to be applied to each of said individual electrodes, said electric charge that has flowed into said electron inversion layer is transferred in a column direction of said photodiodes.

14. The solid-state imaging device according to claim 13, wherein applying a predetermined positive voltage to said individual electrode forms said electron inversion layer so as to be coupled to said region for accumulating said signal charge, so that said signal charge flows into said electron inversion layer and is transferred through said electron inversion layer.

15. The solid-state imaging device according to claim 14, wherein in transferring said signal charge by said electron inversion layer, said signal charge obtained from said plurality of photodiodes is added.

16. The solid-state imaging device according to claim 1, wherein said back-surface electrode is formed in a lattice shape on an element separation region for partitioning said plurality of photodiodes, such that an opening is situated on said photodiode.

17. The solid-state imaging device according to claim 16, wherein said back-surface electrode includes a plurality of individual electrodes provided separately on a column-by-column basis or a row-by-row basis of said photodiodes.

18. The solid-state imaging device according to claim 16, wherein said back-surface electrode is made of a light shielding material.

19. The solid-state imaging device according to claim 1, wherein
a peripheral circuit for controlling an operation of said solid-state imaging device is laid out around a pixel section having an array of said photodiodes; and
a second back-surface electrode is provided on an area corresponding to said peripheral circuit in said back surface of said element substrate.

20. The solid-state imaging device according to claim 19, wherein said second back-surface electrode is provided separately on an analog circuit area and a digital circuit area.
